(19) United States
(12) Patent Application Publication
(10) Pub. No.: US 2023/0016770 A1
(43) Pub. Date: Jan. 19, 2023

(54) METHOD FOR MEASURING RESISTANCE VALUE OF CONTACT PLUG AND TESTING STRUCTURE

(71) Applicant: CHANGXIN MEMORY TECHNOLOGIES, INC., Hefei City (CN)

(72) Inventor: Qiang Long, Hefei (CN)

(21) Appl. No.: 17/502,122

(22) Filed: Oct. 15, 2021

Related U.S. Application Data
(63) Continuation of application No. PCT/CN2021/108039, filed on Jul. 23, 2021.

(30) Foreign Application Priority Data
Jul. 14, 2021 (CN) 202110796988.7

(51) Int. Cl. G01R 27/20; G01R 31/26; H01L 21/66

(52) U.S. Cl. CPC G01R 27/205; G01R 31/2644; H01L 22/34

(57) ABSTRACT

A method for measuring a resistance value of a contact plug is provided. The method includes: providing a structure to be tested, and the structure to be tested including: a plurality of transistors disposed on a substrate in sequence, each transistor including a gate and source-drain doping regions on the substrate and located at two sides of the gate, and two adjacent source-drain doping regions are electrically connected; and a plurality of contact plugs disposed on the substrate in sequence, each transistor being located between two adjacent contact plugs, and bottoms of the contact plugs being electrically connected to the source-drain doping regions; selecting at least two units to be tested from the structure to be tested; obtaining resistance values of respective units to be tested by performing measurement; and determining the resistance value of the contact plug based on the resistance values of the respective unit to be tested.

### CROSS-REFERENCE TO RELATED APPLICATIONS

This application is a continuation of International Application No. PCT/CN2021/108039, filed on Jul. 23, 2021, which is based upon and claims priority to Chinese Patent Application No. 202110796988.7, filed on Jul. 14, 2021. The contents of these applications are hereby incorporated by reference in their entireties.

### BACKGROUND

With the development of technologies, an integrated circuit includes more and more semiconductor devices such as transistors. In order to connect the semiconductor devices, multiple metal layers are usually disposed in the integrated circuit. The semiconductor devices are connected to the metal layers through conductive plugs, and various metal layers are connected through vias. Herein, the conduction between interconnection metal layers and the semiconductor devices, such as the transistor in a substrate is implemented through the contact plugs. With the continuously reduced feature size of the semiconductor devices and continuously improved operation speed, the small change of the resistance value of the contact plug will generate huge influence on the whole integrated circuit. Therefore, it is becoming more and more important to accurately measure the resistance value of the contact plug.

### SUMMARY

This disclosure relates, but is not limited, to a method for measuring a resistance value of a contact plug and a testing structure.

Embodiments of this disclosure provide a method for measuring a resistance value of a contact plug, and the method includes the following operations. A structure to be tested is provided, and the structure to be tested includes: a plurality of transistors disposed on a substrate in sequence, each transistor includes a gate and source-drain doping regions on the substrate and located at two sides of the gate, and two adjacent source-drain doping regions are electrically connected; and a plurality of contact plugs disposed on the substrate in sequence, each transistor is located between two adjacent contact plugs, and the bottoms of the contact plugs are electrically connected to the source-drain doping regions of the transistors. At least two units to be tested are selected from the structure to be tested, each unit to be tested includes multiple contact plugs that are arbitrarily and continuously arranged and all transistors interlaced with the multiple contact plugs. Each unit to be tested has a different number of transistors. The resistance values of respective units to be tested are obtained by performing measurement. The resistance value of the contact plug is determined based on the resistance values of the respective units to be tested.

Embodiments of this disclosure further provide a method for measuring a resistance value of a contact plug of a memory peripheral circuit, and the method includes the above method for measuring the resistance value of the contact plug.

Embodiments of this disclosure further provide a testing structure for a resistance value of a contact plug, and the testing structure includes a plurality of transistors and a plurality of contact plugs. The plurality of transistors are disposed on a substrate in sequence. Each transistor includes the gate and the source-drain doping regions on the substrate and located at two sides of the gate, and two adjacent source-drain doping regions are electrically connected. The plurality of contact plugs are disposed on the substrate in sequence. Each transistor is located between two adjacent contact plugs, and the bottoms of the contact plugs are electrically connected to the source-drain doping regions of the transistors.

Embodiments of this disclosure further provide a testing structure for a resistance value of a contact plug of a memory peripheral circuit, and the testing structure includes the above testing structure for the resistance value of the contact plug.

### BRIEF DESCRIPTION OF THE DRAWINGS

FIG. 1 is a plane schematic diagram of a testing structure for the contact plugs in a related art.

FIG. 2 is a schematic diagram of a circuit structure of a testing structure for the contact plugs in a related art.

FIG. 3 is a flowchart of a method for measuring a resistance value of a contact plug according to embodiments of this disclosure.

FIG. 4 is a schematic diagram of a vertical section of a testing structure according to an embodiment of this disclosure.

FIG. 5 is a schematic diagram of a vertical section of a testing structure according to another embodiment of this disclosure.

FIG. 6 is a plane schematic diagram of a testing structure according to another embodiment of this disclosure.

FIG. 7 is a plane schematic diagram of a circuit structure of a testing structure according to another embodiment of this disclosure.

FIG. 8 is schematic diagram of a characteristic graph that a resistance value of a unit to be tested is changed along the quantity of transistors in the unit to be tested.

FIG. 9 is a schematic diagram of a vertical section of a unit to be tested according to another embodiment of this disclosure.

### REFERENCE SIGNS

101, 411—Metal layer; 103—Active area; 105, 107, 605—Contact plug;

401—Substrate; 403—Source—drain doping region; 405—Dielectric layer; 409—Transistor;

511, 901—First unit to be tested; 513, 903—Second unit to be tested; 515, 905—Third unit to be tested;

601—Gate; 607—First testing pad; 609—Second testing pad;

907—Fourth unit to be tested; 909—Fifth unit to be tested; 911—Sixth unit to be tested.

### DETAILED DESCRIPTION

The following clearly and completely describes the exemplary implementations of this disclosure with reference to the accompanying drawings. Although the drawings show exemplary implementations of this disclosure, it should be understood that this disclosure can be implemented in various forms and shall not be limited by implementations described herein. Instead, providing these implementations is to understand this disclosure thoroughly, and the scope of this disclosure can be completely conveyed to those skilled in the art.

A number of specific details are given below to provide a more thorough understanding of this disclosure. However, it is apparent to those skilled in the art that this disclosure can be implemented without one or more of these details. In other examples, to avoid confusion with this disclosure, some technical features known in the art are not described. That is, all the features of the actual embodiments are not described here, nor are known functions and structures described in detail.

In the drawings, dimensions of layers, areas, components and their relative dimensions may be exaggerated for clarity. The same reference sign throughout represent the same component.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, regions, layers and/or parts may be described with terms first, second, third, etc., these elements, components, regions, layers and/or parts should not be limited to these terms. These terms are used only to distinguish one element, component, region, layer or part from another element, component, region, layer or part. Therefore, a first element, component, region, layer or part discussed below may be represented as a second element, component, region, layer or part without departing from the teaching of this disclosure. However, when discussing a second element, component, region, layer or part, it does not necessarily imply the existence of a first element, component, region, layer or part of this disclosure.

Spatially relational terms such as “below”, “under”, “lower”, “beneath”, “above”, and “upper” may be used herein for convenience of description to describe a relationship between one element or feature and another element or feature illustrated in the drawings. It is to be understood that, in addition to the orientation illustrated in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower. The device may be otherwise oriented (rotated by 90 degrees or in other orientations) and the spatial descriptors used herein may be interpreted accordingly.

The terms used herein are for the purpose of describing specific embodiments only and not intended to limit the disclosure. As used herein, singular forms “a/an”, “one”, and “the” are also intended to include the plural forms, unless otherwise specified in the context. It is also to be understood that, when terms “composed of” and/or “including” are used in this specification, the presence of the features, integers, steps, operations, elements, and/or components is determined, but the presence or addition of one or more other features, integers, steps, operations, elements, components, and/or groups is also possible. As used herein, term “and/or” includes any and all combinations of the related listed items.

In order to thoroughly understand this disclosure, detailed steps and detailed structure will be presented in the following description to explain the technical solution of this disclosure. Optional embodiments of this disclosure are described in details below, however in addition to these detailed descriptions; this disclosure may have other implementations.

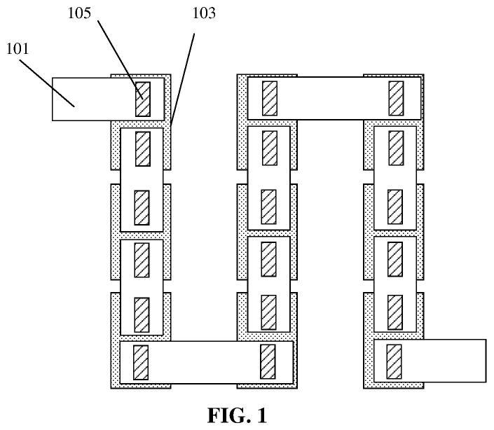

FIG. 1 is a plane structural schematic diagram of a testing structure for the contact plugs in a related art. As illustrated in FIG. 1, the current testing structure includes the metal layers 101, the active areas 103 and the contact plugs 105. Herein, the bottoms of the contact plugs 105 are coupled to the active areas 103, and the tops of the contact plugs 105 are coupled to the metal layers 101. The adjacent contact plugs are electrically connected through the active areas or the metal layers so as to form a serial structure, and this kind of testing structure is referred as a chain contact structure. The head metal layer and tail metal layers of the chain contact structure are coupled to the testing pads respectively, so as to input and output testing signals.

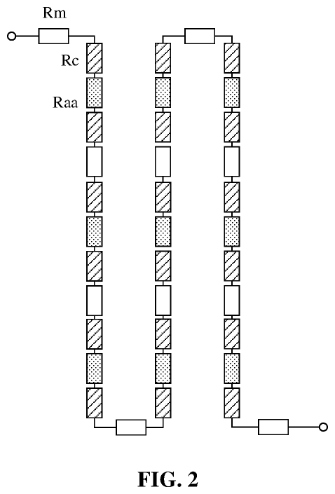

FIG. 2 is a schematic diagram of a circuit structure of a testing structure for the contact plugs in a related art. As illustrated in FIG. 2, the resistance of the whole testing structure is obtained by serially connecting the resistance Rc of the contact plugs, the resistance Raa of the active areas and the resistance Rm of the metal layers. In combination with FIG. 1 and FIG. 2, testing current is obtained by applying testing voltage. The resistance of the metal layers at the upper layer and the resistance of the active areas are much less than the resistance of the contact plugs, so they may be omitted. The total resistance value of the testing circuit is obtained through the testing voltage and the testing current, the resistance value is divided by the number of contact plugs so as to obtain the resistance value of the single contact plug. The resistance value of the single contact plug is compared with that (empirical value or expected value) of the contact plugs well connected, if there is a great difference, the contact plugs are determined to be unqualified. Otherwise, the contact plugs are qualified. However, the actual testing result shows that the testing structure is still difficult to find the defects of the contact plugs.

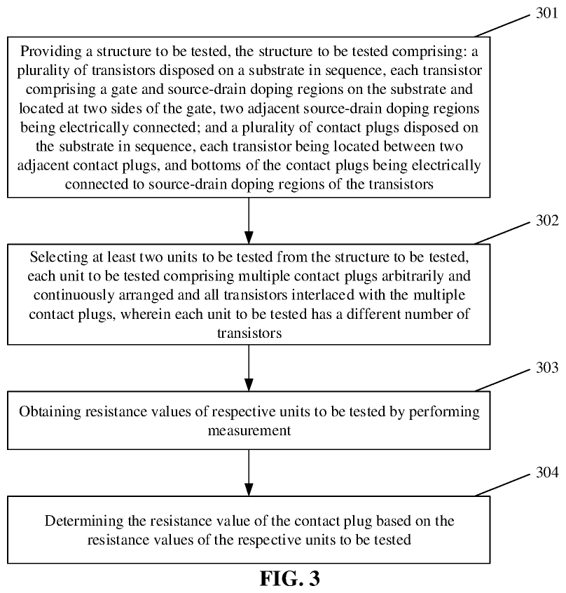

Base on this, embodiments of this disclosure provide a method for measuring a resistance value of a contact plug. Referring to FIG. 3, the method includes the steps S301 to S304.

At step S301, a structure to be tested is provided, and the structure to be tested includes: a plurality of transistors disposed on a substrate in sequence, each transistor includes a gate and source-drain doping regions on the substrate and located at the two sides of the gate, and the source-drain doping regions of two adjacent transistors are electrically connected; and a plurality of contact plugs disposed on the substrate in sequence, each transistor is located between two adjacent contact plugs, and the bottoms of the contact plugs are electrically connected to the source-drain doping regions of the transistors.

At step S302, at least two units to be tested are selected from the structure to be tested. Each unit to be tested includes multiple contact plugs arbitrarily and continuously arranged and all transistors interlaced with the multiple contact plugs, and each unit to be tested has a different number of transistors.

At step S303, the resistance values of the respective units to be tested are obtained by performing measurement.

At step S304, the resistance value of the contact plug is determined based on the resistance values of the respective units to be tested.

Thus, the testing structure is closer to the actual disclosure structure of the integrated circuit, and the testing structure can reflect the process condition of the contact plugs. The resistance values of different units to be tested are obtained by serially connecting different quantities of transistors, so the resistance value of the contact plug may be accurately deduced.

The method for measuring the resistance value of the contact plug provided by embodiments of this disclosure is described in details below in combination with FIG. 3 to FIG. 9.

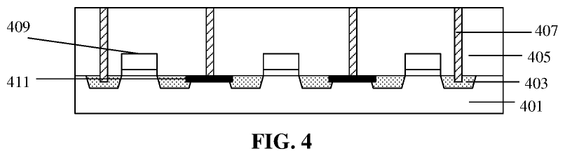

Firstly, step S301 is performed, and the structure to be tested is provided. FIG. 4 is a schematic diagram of a vertical section of a testing structure according to embodiments of this disclosure. As illustrated in FIG. 4, the structure to be tested includes: a plurality of transistors 409 disposed on the substrate 401 in sequence, each transistor 409 includes a gate and source-drain doping regions 403 on the substrate 401 and located at the two sides of the gate, and two adjacent source-drain doping regions 403 are electrically connected; and a plurality of contact plugs 407 disposed on the substrate in sequence, each transistor 409 is located between two adjacent contact plugs 407, and the bottoms of the contact plugs 407 are electrically connected to the source-drain doping regions 403 of the transistors 409.

In an actual operation, the transistors 409 may be Metal Oxide Semiconductor Transistors (MOS), for example, P-type Metal Oxide Semiconductor Transistors (PMOS) or N-type Metal Oxide Semiconductor Transistors (NMOS). The substrate 401 further includes a dielectric layer 405, which covers the substrate and the transistors 409, and the contact plugs 407 are formed in the dielectric layer 405.

Herein, the electric connection of two adjacent source-drain doping regions 403 may be implemented by the metal layers 411 spanning the source-drain doping regions 403 of two adjacent transistors 409. In some other embodiments, the source-drain doping regions 403 of two adjacent transistors 409 may implement the electric connection (not illustrated in the figure) by an overlapping part.

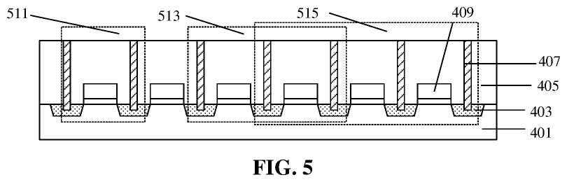

In another embodiment, as illustrated in FIG. 5, two adjacent transistors 409 share a same source-drain doping region 403. By sharing a same source-drain doping region 403, adjacent transistors 409 are made to implement serial connection with each other. It is to be understood that, compared with the resistance of the whole transistors 409, the resistance of the metal layer 411 and the resistance of the source-drain doping region 403 of the transistor are very small. The various ways of implementing the electric connection of the source-drain doping regions provided in this disclosure have little influence on the measurement result of the final resistance value of the contact plugs, and may be ignored.

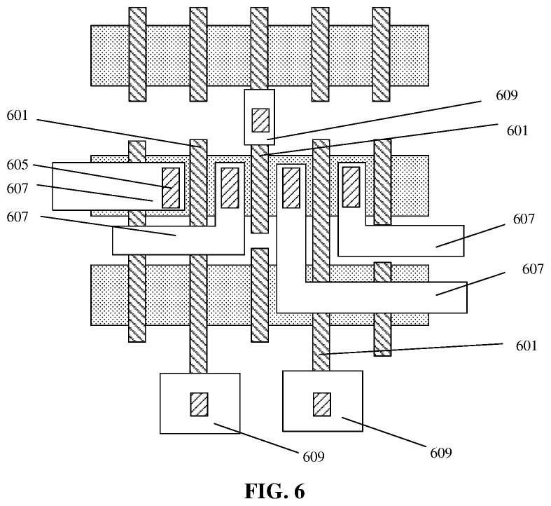

In some implementations, as illustrated in FIG. 6, the structure to be tested further includes a plurality of first testing pads 607 and a plurality of second testing pads 609, each of the first testing pads 607 is electrically connected to a respective contact plug 605, and each of the second testing pads 609 is electrically connected to the gate 601 of a respective transistor.

In an actual operation, the materials of the first testing pads 607 and the second testing pads 609 may be, for example, conductive material, which includes, but is not limited to Tungsten (W), Cobalt (Co), Copper (Cu), Aluminum (Al), polycrystalline silicon, doped silicon, silicide or any combination thereof. The use of the testing pads for rewiring can improve the space utilization rate of the integrated circuit, and can avoid the direct measurement of the contact plugs, so as to prevent the damage to the contact plugs caused by direct physical contact during a measurement process, and improve the reliability of the testing structure.

Then step S302 is performed, and at least two units to be tested are selected from the structure to be tested. Each unit to be tested includes multiple contact plugs arbitrarily and continuously arranged and all transistors interlaced with the multiple contact plugs, and each unit to be tested has a different number of transistors.

Taking the implementation of selecting three units to be tested from the structure to be tested as an example, the selection manner of the units to be tested is specified. As illustrated in the dotted boxes of FIG. 5, a first unit 511 to be tested, a second unit 513 to be tested and a third unit 515 to be tested are selected from the structure to be tested. The first unit 511 to be tested includes two contact plugs and a transistor disposed between the contact plugs, the second unit 513 to be tested includes three contact plugs and two transistors among the contact plugs, and the third unit 515 to be tested includes four contact plugs and three transistors among the contact plugs.

It is to be understood that the above technical solution for selecting three units to be tested is only an example for the implementation of this disclosure, and more units to be tested may be selected in other embodiments.

Then step S303 is performed, and the resistance values of the respective units to be tested are obtained by performing measurement.

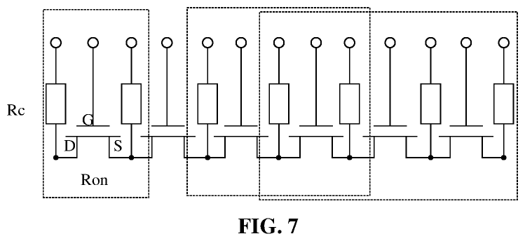

FIG. 7 is a schematic diagram of a circuit structure of a testing structure according to embodiments of this disclosure. The specific method for measuring the resistance value of each unit to be tested in the embodiments of this disclosure is described in combination with FIG. 5 and FIG. 7.

In an embodiment, the operation of obtaining the resistance value of each unit to be tested by performing measurement includes the following operations. The testing work voltage is applied to one of two contact plugs located at the outermost side of each unit to be tested, another contact plug is grounded, and other contact plugs are floated. All transistors included in each unit to be tested are conducted by applying a work voltage to the gates included in a respective unit to be tested. The testing current flowing through each unit to be tested is measured, and the resistance value of each unit to be tested is obtained based on a respective testing voltage and a respective testing current.

Specifically, according to FIG. 5 and FIG. 7, the operation of obtaining the resistance value of the first unit to be tested by performing measurement includes: the testing voltage is applied to one of two contact plugs located at the outermost side of the first unit 511 to be tested, and another contact plug is grounded. For example, the contact plug connected to the source-drain contact area as a source is grounded, and the contact plug connected to the source-drain contact area as a drain is connected to the testing voltage. Meanwhile, the work voltage is applied to the gates of the transistors in the first unit 511 to be tested, so that all transistors included in the unit 511 to be tested are conducted, and the remaining contact plugs in the first unit 511 to be tested are floated. At this case, the testing current flowing through the first unit 511 to be tested is measured, and the testing voltage is divided by the testing current to obtain the resistance value of the first unit to be tested, for example, the resistance value is marked as R1.

The operation of obtaining the resistance value of the second unit to be tested by performing measurement includes: the testing voltage is applied to one of two contact plugs of the second unit 513 to be tested, and another contact plug is grounded. For example, the contact plug connected to the source-drain contact area as a source is grounded, and the contact plug connected to the source-drain contact area as a drain is connected to the testing voltage. Meanwhile, the work voltage is applied to the gates of the transistors in the second unit 513 to be tested, so that all transistors included in the unit 513 to be tested are conducted, and the remaining contact plugs in the second unit 513 to be tested are floated. At this case, the testing current flowing through the second unit 513 to be tested is measured, and the testing voltage is divided by the testing current to obtain the resistance value of the second unit to be tested, for example, the resistance value is marked as R2.

The operation of obtaining the resistance value of the third unit to be tested by performing measurement includes: the testing voltage is applied to one of two contact plugs of the third unit 515 to be tested, and another contact plug is grounded. For example, the contact plug connected to the source-drain contact area as a source is grounded, and the contact plug connected to the source-drain contact area as a drain is connected to the testing voltage. Meanwhile, the work voltage is applied to the gates of the transistors in the third unit 515 to be tested, so that all transistors included in the unit 515 to be tested are conducted, and the remaining contact plugs in the third unit 515 to be tested are floated. At this case, the testing current flowing through the third unit 515 to be tested is measured. The testing voltage is divided by the testing current to obtain the resistance value of the third unit to be tested, for example, the resistance value is marked as R3.

In a specific embodiment, the operation of obtaining the resistance values of the respective units to be tested by performing measurement further includes: the gates of the remaining transistors other than a unit to be tested in the structure to be tested and the remaining contact plugs are floated.

Specifically, for example, when the first unit 511 to be tested is measured, the gates of the remaining transistors other than the first unit 511 to be tested and other contact plugs are floated. By floating the gates of the remaining transistors other than the unit to be tested in the structure to be tested and the contact plugs, the noise disturbance of other components, such as the adjacent transistors may be excluded when measuring the current flowing through the unit to be tested, and then the testing accuracy is improved.

Then step S304 is performed, and the resistance value of the contact plug is determined based on the resistance values of the respective units to be tested.

In an embodiment, the operation of determining the resistance value of the contact plug based on the resistance values of the respective units to be tested includes: the characteristic graph that the resistance values of the units to be tested are changed along the quantities of the transistors in the respective units to be tested based on the measured resistance values of the respective units to be tested and the quantities of the transistors included in the respective units to be tested, and the resistance value of the contact plug is obtained based on the characteristic graph.

In a specific embodiment, the operation of obtaining the characteristic graph that the resistance values of the respective units to be tested are changed along the quantities of the transistors in the respective units to be tested includes the following operations. A two dimensional coordinate system is established by taking X-axis as the quantities of the transistors in the respective units to be tested and taking Y-axis as the resistance values of the respective units to be tested. Discrete points are made in the two dimensional coordinate system according to the different quantities of the transistors in the units to be tested and the resistance values of the corresponding units to be tested, and the discrete points are subjected to linear fitting so as to obtain the characteristic graph that the resistance values of the respective units to be tested are changed along the quantities of the transistors in the respective units to be tested.

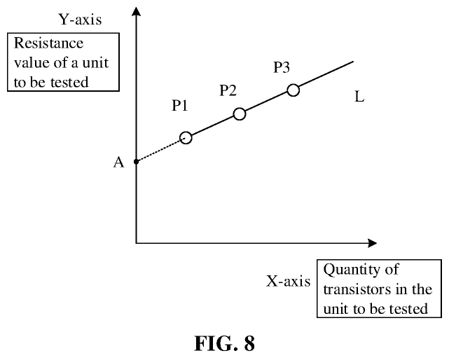

In an actual operation, firstly, the two dimensional coordinate system is established, the horizontal axis is the quantity of the transistors in the unit to be tested, and the vertical axis is the testing resistance value of the unit to be tested. Taking the selection of three units to be tested as an example, the first unit 511 to be tested includes one transistor, the second unit 513 to be tested includes two transistors, and the third unit 515 to be tested includes three transistors. The measuring resistance value of the first unit to be tested is R1, the measuring resistance value of the second unit to be tested is R2, and the measuring resistance value of the third unit to be tested is R3. As illustrated in FIG. 8, three discrete points P1, P2 and P3 corresponding to the first unit to be tested, the second unit to be tested and the third unit to be tested respectively are made in the two dimensional coordinate system according to the quantities of the transistors in the first unit to be tested, the second unit to be tested and the third unit to be tested and the measuring resistance values. And then, as illustrated in FIG. 8, after obtaining the above discrete points, the discrete points are subjected to linear fitting, so as to obtain the characteristic graph L that the resistance value of the unit to be tested is changed along the quantity of transistors in the unit to be tested.

In an embodiment, in order to obtain the resistance value of the contact plug based on the characteristic graph L, the operation of obtaining the resistance of the contact plug based on the characteristic graph may include following operations. The resistance value of a corresponding unit to be tested on the characteristic graph is obtained when the quantity of the transistors in the corresponding unit to be tested is 0, and the resistance value is marked as the fitting resistance value. A half of the fitting resistance value is determined as the resistance value of the contact plug.

In an actual operation, in combination with FIG. 8, when the quantity of the transistors in the unit to be tested is 0, the resistance value of the corresponding unit to be tested on the characteristic graph may be determined by the following method: the characteristic graph L is prolonged, and the vertical axis value corresponding to the intersection point of the characteristic graph L and the vertical axis is the resistance value of the corresponding unit to be tested on the characteristic graph when the quantity of the transistors in the unit to be tested is 0. As illustrated in FIG. 8, the intersection point A of the characteristic graph L and the vertical axis is the corresponding feature point when the quantity of the transistors in the unit to be tested is 0, and the vertical axis value corresponding to the point A is the fitting resistance value, for example, R0.

In combination with FIG. 7, it can be seen that the resistance value R1 of the first unit 511 to be tested is equal to the sum of the resistance values of the outermost two contact plugs and the resistance value of one transistor located between the outermost two contact plugs, and specifically R1=2Rc+Ron. The resistance value R2 of the second unit 513 to be tested is equal to the sum of the resistance values of the outermost two contact plugs and the resistance values of two transistors located between the outermost two contact plugs, and specifically R2=2Rc+2Ron. The resistance value R3 of the third unit 515 to be tested is equal to the sum of the resistance values of the outermost two contact plugs and the resistance values of three transistors located between the outermost two contact plugs, specifically R3=2Rc+3Ron, and so on; the resistance value of the N+1 unit to be tested is RN=2Rc+NRon. Thus, it can be seen that when the quantity of the transistor in the unit to be tested is 0, R0=2Rc, and R0 is the fitting resistance value R0.

It can be seen from the above analysis that the resistance Rc of the contact plug is equal to a half of the fitting resistance value. Thus, the resistance value Rc of the contact plug is measured.

It is to be understood that the above technical solution of selecting three groups of different units to be tested as the fitting characteristic graph of the discrete points is only an example for the implementation of this disclosure, and in other embodiments, more units to be tested may be selected as the fitting characteristic graph of the discrete points.

In another embodiment, for example, the structure to be tested includes: N+1 contact plugs and N transistors, and the ith transistor is located between the ith contact plug and the i+1th contact plug. N is a positive integer greater than or equal to 2, and i is a positive integer less than or equal to N. The operation of selecting at least two units to be tested from the structure to be tested includes: N units to be tested are selected, and each of the transistor is at least included by one unit to be tested.

It is possible to ensure that each contact plug is tested at least once in a manner that each of the transistors is at least included in one unit to be tested, so as to avoid the influence of the difference of the resistance value of each contact plug due to the process error on the measurement accuracy.

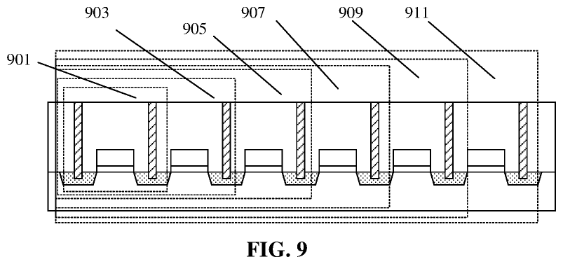

In a specific embodiment, as illustrated in FIG. 9, the operation of selecting N units to be tested and each of the transistor is at least included in one unit to be tested includes: the 1st, the 2nd . . . the Nth units to be tested are selected respectively. Herein, the ith unit to be tested includes the first contact plug and the i+1th contact plug, the ith transistor is located between the first contact plug and the i+1th contact plug, and i is a positive integer less than or equal to N.

In an actual operation, as illustrated in FIG. 9, the above solution is specifically described by taking N=6 as an example. When N=6, the structure to be tested includes six transistors. According to the above solution, N=6 units to be tested may be selected during the measurement. As illustrated in FIG. 9, the structure to be tested in this embodiment includes seven contact plugs and six transistors, which are, from left to right, 1st to 7th contact plugs and 1st to 6th transistors, respectively. As illustrated in dotted box of FIG. 9, the first unit 903 to be tested is selected, and the first unit to be tested includes the first contact plug, the second contact plug and one transistor located between the first contact plug and the second contact plug. Similarly, the sixth unit 911 to be tested is selected, and the sixth unit to be tested includes the first contact plug, the seventh contact plug, and six transistors located between the first contact plug and the seventh contact plug. As illustrated in dotted box of FIG. 9, the 1st unit to be tested to the 6th unit to be tested are 901, 903, 905, 907, 909 and 911, respectively.

Through the above selection manner for the unit to be tested, that the maximum number of units to be tested may be selected while ensuring that each contact plug is measured once, and the measurement accuracy can be greatly improved by maximizing the number of the unit to be tested.

In another embodiment, the operation of selecting at least two units to be tested from the structure to be tested includes: two units to be tested are selected, and marked as the first unit to be tested and the second unit to be tested respectively. The first unit to be tested includes m+1 contact plugs arbitrarily and continuously arranged and m transistors interlaced with the m+1 contact plugs. The second unit to be tested includes n+1 contact plugs arbitrarily and continuously arranged and n transistors interlaced with the n+1 contact plugs, m is not equal to n, and m and n are positive integers. The operation of obtaining the resistance values of the respective units to be tested by performing measurement includes: the resistance value R1 of the first unit to be tested and the resistance value R2 of the second unit to be tested are measured respectively. The operation of determining the resistance value of the contact plug according to the resistance values of the units to be tested includes: the resistance value R of the contact plug is obtained by calculating the following formula:

$$R = \vert \frac{n R 1 - m R 2}{2 n - 2 m} \vert .$$

Specifically, for example, the first unit to be tested may include m+1 contact plugs arbitrarily and continuously arranged and m transistors interlaced with the m+1 contact plugs. The second unit to be tested includes n+1 contact plugs arbitrarily and continuously arranged and n transistors interlaced with the n+1 contact plugs, the resistance value R1 of the first unit to be tested and the resistance value R2 of the second unit to be tested are measured respectively. Herein R1=2Rc+mRon, R2=2Rc+nRon, thus the resistance of the contact plug may be obtained as

$$R = \vert \frac{n R 1 - m R 2}{2 n - 2 m} \vert .$$

For the technical solution that only two units to be tested are selected, in addition to using the graph fitting manner in the abovementioned embodiments to the resistance value of the contact plug, the embodiment may provide a manner that only adopts a calculation formula rather than the graph fitting, which is more efficient compared to the graph fitting.

In some other embodiments, the method for measuring the resistance value of the contact plug provided by the embodiments of this disclosure may be applied to any structure including the contact plug, for example, the measurement for the resistance value of the contact plug of the memory peripheral circuit.

Embodiments of this disclosure further provide a testing structure for a resistance value of a contact plug. Referring to FIG. 4, the structure to be tested includes: a plurality of transistors 409 that are disposed on the substrate 401 in sequence, each transistor 409 includes a gate and source-drain doping regions 403 on the substrate 401 and located at the two sides of the gate, and two adjacent source-drain doping regions 403 are electrically connected; and a plurality of contact plugs 407 that are disposed on the substrate in sequence, each of the transistors 409 is located between two adjacent contact plugs 407, and the bottoms of the contact plugs 407 are electrically connected to the source-drain doping regions 403 of the transistors 409.

In an actual operation, the transistors 409 may be MOS, for example, PMOS or NMOS. The substrate 401 further includes a dielectric layer 405, which covers the substrate and the transistors 409, and the contact plugs 407 are formed in the dielectric layer 405.

Herein, the electric connection of two adjacent source-drain doping regions 403 may be implemented by the metal layers 411 spanning the source-drain doping regions 403 of two adjacent transistors 409. In other embodiments, the source-drain doping regions 403 of two adjacent transistors 409 may implement the electric connection (not illustrated in the figure) by an overlapping part.

In another embodiment, as illustrated in FIG. 5, two adjacent transistors 409 share a same source-drain doping region 403. By sharing a source-drain doping region 403, adjacent transistors 409 are made to implement serial connection with each other. It is to be understood that, compared with the resistance of the whole transistors 409, the resistance of the metal layer 411 and the resistance of the source-drain doping region 403 of the transistor are very small. The various ways of implementing the electric connection of the source-drain doping region provided in this disclosure have little influence on the measurement result of the final resistance value of the contact plug, and may be ignored.

In some implementations, as illustrated in FIG. 6, the structure to be tested further includes a plurality of first testing pads 607 and a plurality of second testing pads 609, each of the first testing pads 607 is electrically connected to a respective the contact plugs 605, and each of the second testing pads 609 is electrically connected to the gate 601 of a respective transistor.

In an actual operation, the materials of the first testing pads 607 and the second testing pads 609 may be, for example, conductive material, which includes, but is not limited to W, Co, Cu, Al, polycrystalline silicon, doped silicon, silicide, or any combination thereof. The use of the testing pads for rewiring can improve the space utilization rate of the integrated circuit, and can avoid the direct measurement of the contact plugs, so as to prevent the damage to the contact plugs caused by direct physical contact during a measurement process, and improve the reliability of the testing structure.

In an actual operation, the testing structure for the resistance value of the contact plug provided by the embodiments of this disclosure may be applied to any structure including the contact plug, for example, the measurement for the resistance value of the contact plug of the memory peripheral circuit.

In conclusion, the testing structure of this disclosure is closer to the actual structure of the integrated circuit application, and the testing structure can reflect the process condition of the contact plugs. The resistance values of different units to be tested are obtained by serially connecting different quantities of transistors, so the resistance value of the contact plug may be accurately inferred.

It is to be understood that the measurement method and the testing structure for the resistance value of the contact plug provided by this disclosure may be applied to any structure including the contact plug, and do not limit the field of the memory. Various technical features in the technical solution recorded in various embodiments may be arbitrarily combined without conflict.

The above is only optional embodiments of this disclosure and is not intended to limit the protection scope of this disclosure. Any modifications, equivalent replacements, improvements and the like made within the spirit and principle of this disclosure shall fall within the protection scope of this disclosure.

1. A method for measuring a resistance value of a contact plug, comprising:
providing a structure to be tested, the structure to be tested comprising: a plurality of transistors disposed on a substrate in sequence, each transistor comprising a gate and source-drain doping regions on the substrate and located at two sides of the gate, two adjacent source-drain doping regions being electrically connected; and a plurality of contact plugs disposed on the substrate in sequence, each transistor being located between two adjacent contact plugs, and bottoms of the contact plugs being electrically connected to source-drain doping regions of the transistors;
selecting at least two units to be tested from the structure to be tested, each unit to be tested comprising multiple contact plugs arbitrarily and continuously arranged and all transistors interlaced with the multiple contact plugs, wherein each unit to be tested has a different number of transistors;
obtaining resistance values of respective units to be tested by performing measurement; and
determining the resistance value of the contact plug based on the resistance values of the respective units to be tested.

2. The method of claim 1, wherein two adjacent transistors share a same source-drain doping region.

3. The method of claim 1, wherein determining the resistance value of the contact plug based on the resistance values of the respective units to be tested comprises:
obtaining a characteristic graph that the resistance values of the respective units to be tested are changed along quantities of transistors in the respective units to be tested based on the measured resistance values of the respective units to be tested and the quantities of transistors included in the respective units to be tested; and
obtaining the resistance value of the contact plug based on the characteristic graph.

4. The method of claim 3, wherein obtaining the characteristic graph that the resistance values of the respective units to be tested are changed along the quantities of transistors in the respective units to be tested comprises:
establishing a two dimensional coordinate system by taking X-axis as the quantities of transistors in the respective units to be tested and taking Y-axis as the resistance values of the respective units to be tested;
making discrete points in the two dimensional coordinate system according to different quantities of transistors in the units to be tested and resistance values of corresponding units to be tested; and
obtaining the characteristic graph that the resistance values of the respective units to be tested are changed along the quantities of transistors in the respective units to be tested by performing linear fitting to the discrete points.

5. The method of claim 3, wherein obtaining the resistance value of the contact plug based on the characteristic graph comprises:
obtaining a resistance value of a corresponding unit to be tested on the characteristic graph when a quantity of transistors in the corresponding unit to be tested is 0, marking the resistance value as a fitting resistance value; and
determining a half of the fitting resistance value as the resistance value of the contact plug.

6. The method of claim 1, wherein obtaining the resistance values of the respective units to be tested by performing measurement comprises:
applying a testing voltage to one of two contact plugs located at outermost side of the respective unit to be tested, and grounding another contact plug;
conducting all transistors included in the respective unit to be tested by applying a work voltage to gates of the all transistors included in the respective unit to be tested;
measuring a testing current flowing through the respective unit to be tested; and
obtaining a resistance value of the respective unit to be tested based on the testing voltage and the testing current.

7. The method of claim 6, wherein obtaining the resistance values of the respective units to be tested by performing measurement further comprises:
floating gates of remaining transistors other than the respective unit to be tested in the structure to be tested and other contact plugs.

8. The method of claim 1, wherein the structure to be tested further comprises:
a plurality of first testing pads and a plurality of second testing pads, each first testing pad being electrically connected to a respective contact plug, and each second testing pad being electrically connected to a gate of a respective transistor.

9. The method of claim 1, wherein the structure to be tested comprises: N+1 contact plugs and N transistors, an ith transistor is located between an ith contact plug and an (i+1)th contact plug, N is a positive integer greater than or equal to 2, and i is a positive integer less than or equal to N; and
selecting the at least two units to be tested from the structure to be tested comprising: selecting N units to be tested, and each transistor being included in at least one unit to be tested.

10. The method of claim 9, wherein selecting the N units to be tested, and each transistor being included in at least one unit to be tested comprises:
selecting a first unit to be tested, a second unit to be tested, . . . , and an Nth unit to be tested, respectively;
wherein an ith unit to be tested comprises a first contact plug, an (i+1)th contact plug, and i transistors located between the first contact plug and the (i+1)th contact plug, and i is a positive integer less than or equal to N.

11. The method of claim 1, wherein selecting the at least two units to be tested from the structure to be tested comprises:
selecting two units to be tested including a first unit to be tested and a second unit to be tested; the first unit to be tested comprising m+1 contact plugs arbitrarily and continuously arranged and m transistors interlaced with the m+1 contact plugs; the second unit to be tested comprising n+1 contact plugs arbitrarily and continuously arranged and n transistors interlaced with the n+1 contact plugs, m being not equal to n, and m and n being positive integers;
obtaining the resistance values of the respective units to be tested by performing measurement comprises: measuring a resistance value R1 of the first unit to be tested and a resistance value R2 of the second unit to be tested respectively; and
determining the resistance value of the contact plug based on the resistance values of the respective units to be tested comprises: obtaining a resistance value R of the contact plug by calculating a following formula:
$$R = \vert \frac{n R 1 - m R 2}{2 n - 2 m} \vert .$$

12. A method for measuring a resistance value of a contact plug of a memory peripheral circuit, comprising:
providing a structure to be tested, the structure to be tested comprising: a plurality of transistors disposed on a substrate in sequence, each transistor comprising a gate and source-drain doping regions on the substrate and located at two sides of the gate, two adjacent source-drain doping regions being electrically connected; and a plurality of contact plugs disposed on the substrate in sequence, each transistor being located between two adjacent contact plugs, and bottoms of the contact plugs being electrically connected to source-drain doping regions of the transistors;
selecting at least two units to be tested from the structure to be tested, each unit to be tested comprising multiple contact plugs arbitrarily and continuously arranged and all transistors interlaced with the multiple contact plugs, wherein each unit to be tested has a different number of transistors;
obtaining resistance values of respective units to be tested by performing measurement; and
determining the resistance value of the contact plug based on the resistance values of the respective units to be tested.

13. The method claim 12, wherein two adjacent transistors share a same source-drain doping region.

14. The method of claim 12, wherein determining the resistance value of the contact plug based on the resistance values of the respective units to be tested comprises:
obtaining a characteristic graph that the resistance values of the respective units to be tested are changed along quantities of transistors in the respective units to be tested based on the measured resistance values of the respective units to be tested and the quantities of transistors included in the respective units to be tested; and
obtaining the resistance value of the contact plug based on the characteristic graph.

15. The method of claim 14, wherein obtaining the characteristic graph that the resistance values of the respective units to be tested are changed along the quantities of transistors in the respective units to be tested comprises:
establishing a two dimensional coordinate system by taking X-axis as the quantities of transistors in the respective units to be tested and taking Y-axis as the resistance values of the respective units to be tested;
making discrete points in the two dimensional coordinate system according to different quantities of transistors in the units to be tested and resistance values of corresponding units to be tested; and
obtaining the characteristic graph that the resistance values of the respective units to be tested are changed along the quantities of transistors in the respective units to be tested by performing linear fitting to the discrete points.

16. The method of claim 14, wherein obtaining the resistance value of the contact plug based on the characteristic graph comprises:
obtaining a resistance value of a corresponding unit to be tested on the characteristic graph when a quantity of transistors in the corresponding unit to be tested is 0, marking the resistance value as a fitting resistance value; and
determining a half of the fitting resistance value as the resistance value of the contact plug.

17. A testing structure for a resistance value of a contact plug, comprising:
a plurality of transistors disposed on a substrate in sequence;
each transistor comprising a gate and source-drain doping regions on the substrate and located at two sides of the gate, and two adjacent source-drain doping regions being electrically connected; and
a plurality of contact plugs disposed on the substrate in sequence;
each transistor being located between two adjacent contact plugs, and bottoms of the contact plugs are electrically connected to source-drain doping regions of the transistors.

18. The testing structure of claim 17, wherein two adjacent transistors share a same source-drain doping region.

19. The testing structure of claim 17, further comprising:
a plurality of first testing pads and a plurality of second testing pads, each first testing pad being electrically connected to a respective contact plug, and each second testing pad being electrically connected to a gate of a respective transistor.

20. A testing structure for a resistance value of a contact plug of a memory peripheral circuit, comprising the testing structure of claim 17.
